(19) United States
(12) Patent Application Publication
(10) Pub. No.: US 2020/0296832 A1
(43) Pub. Date: Sep. 17, 2020

(54) PRINTED CIRCUIT BOARD ASSEMBLY FORMING A LIGHTING PATTERN

(71) Applicant: Current Lighting Solutions, LLC, East Cleveland, OH (US)

(72) Inventor: Benjamin Noble TAZIRI, Longmont, OH (US)

(21) Appl. No.: 16/352,874

(22) Filed: Mar. 14, 2019

(51) Int. Cl. H05K 1/14; F21V 23/06; F21V 23/00; H05K 1/02

(52) U.S. Cl. CPC H05K 1/142; F21V 23/06; F21Y 2115/10; H05K 1/0209; F21V 23/005

(57) ABSTRACT

Provided is a printed circuit board (PCB) assembly that includes a plurality of printed circuit boards to be electrically connected together, and each being formed of a first shape and having a plurality of lighting elements arranged thereon to form of a second shape creating a lighting pattern of a desired shape with the plurality of lighting elements, when electrically connected together. The first shape of the printed circuit boards being different from the second shape of the arrangement of the lighting elements.

### FIELD

The invention relates generally to a printed circuit board (PCB) assembly. In particularly, the present invention relates to a PCB assembly having circuits arranged to form specific shapes.

### BACKGROUND

In some lighting assemblies, to obtain a specific-shaped light emitting diode (LED) lighting arrangement, the PCBs are formed to match the shape of a desired lighting arrangement. For example, as shown in FIG. 1, the PCB 10 is shaped in an arc shape and comprises a plurality of LEDs 20 disposed in a corresponding shape. A plurality of these arc shaped PCBs 10 (e.g., four) are arranged together to create a circular shaped lighting arrangement.

Special circular PCB routing is necessary to electrically connect the PCBs 10 together to create the circular shaped lighting arrangement, which can be time-consuming and cause undesirable costs to be incurred.

### SUMMARY OF THE EMBODIMENTS

Given the aforementioned deficiencies, it is desirable to have a PCB assembly capable of creating specific lighting patterns without the inconvenience of special wiring to achieve the electrical connections between the PCBs.

In one exemplary embodiment, PCB assembly is provided. The PCB assembly includes a plurality of PCBs to be electrically connected, and each being formed of a first shape and having a plurality of lighting elements arranged thereon to form of a second shape creating a lighting pattern of a desired shape with the plurality of lighting elements, when electrically connected together. The first shape of the printed circuit boards being different from the second shape of the arrangement of the lighting elements.

In another exemplary embodiment, a lighting assembly including the PCB assembly is also provided.

The foregoing has broadly outlined some of the aspects and features of various embodiments, which should be construed to be merely illustrative of various potential applications of the disclosure. Other beneficial results can be obtained by applying the disclosed information in a different manner or by combining various aspects of the disclosed embodiments. Accordingly, other aspects and a more comprehensive understanding may be obtained by referring to the detailed description of the exemplary embodiments taken in conjunction with the accompanying drawings, in addition to the scope defined by the claims.

### DESCRIPTION OF THE DRAWINGS

FIG. 1 is a printed circuit board having LEDs of a conventional lighting assembly.

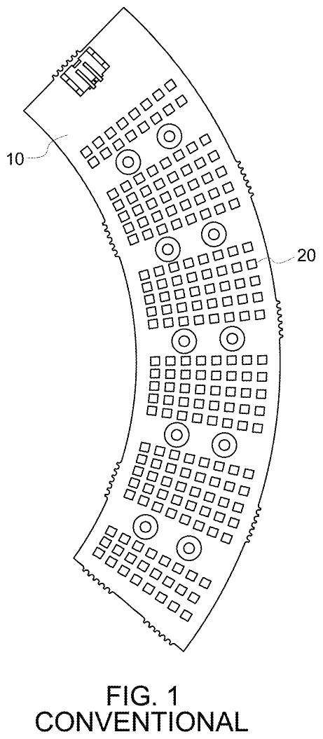

FIG. 2 is a PCB assembly for a lighting assembly, according to one or more exemplary embodiments of the present invention.

FIG. 3 is a PCB of the PCB assembly of FIG. 2, according to one or more exemplary embodiments of the present invention.

FIG. 4 is a perspective view of PCB assembly of FIG. 2 within a lighting assembly, showing the electrical connection between the PCBs, according to one or more exemplary embodiments of the present invention.

FIGS. 5 and 6 depict PCB assemblies according to alternative embodiments of the present invention, with use of the PCBs as shown in FIGS. 2 through 4 being connected to form different lighting patterns.

The drawings are only for purposes of illustrating preferred embodiments and are not to be construed as limiting the disclosure. Given the following enabling description of the drawings, the novel aspects of the present disclosure should become evident to a person of ordinary skill in the art. This detailed description uses numerical and letter designations to refer to features in the drawings. Like or similar designations in the drawings and description have been used to refer to like or similar parts of embodiments of the invention.

### DETAILED DESCRIPTION OF THE EMBODIMENTS

As required, detailed embodiments are disclosed herein. It must be understood that the disclosed embodiments are merely exemplary of various and alternative forms. As used herein, the word “exemplary” is used expansively to refer to embodiments that serve as illustrations, specimens, models, or patterns. The figures are not necessarily to scale and some features may be exaggerated or minimized to show details of particular components.

In other instances, well-known components, systems, materials, or methods that are known to those having ordinary skill in the art have not been described in detail in order to avoid obscuring the present disclosure. Therefore, specific structural and functional details disclosed herein are not to be interpreted as limiting, but merely as a basis for the claims and as a representative basis for teaching one skilled in the art.

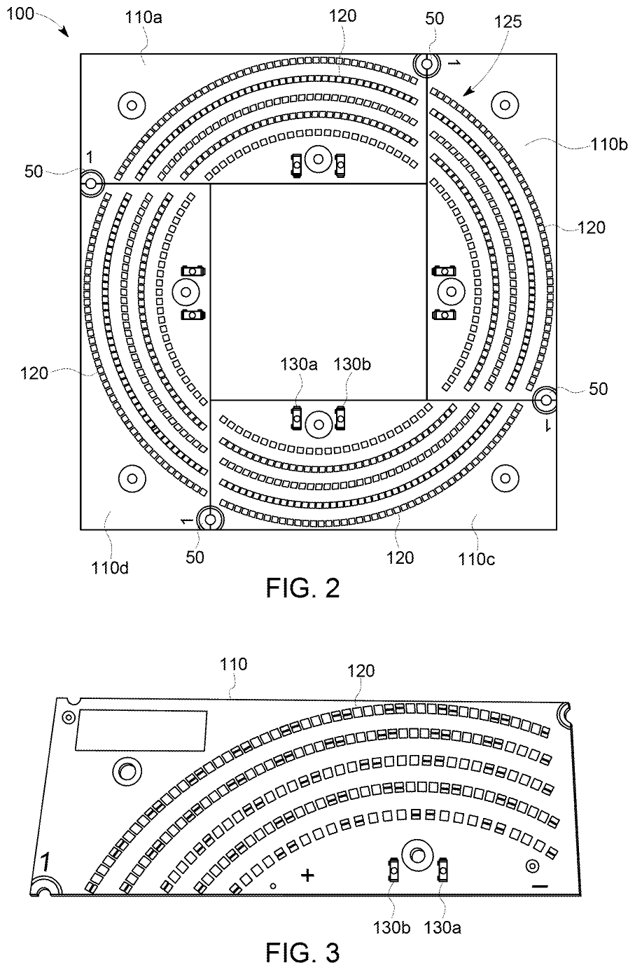

Exemplary embodiments of the present invention provide a PCB assembly capable of creating lighting patterns with lighting elements without special PCB wiring routing. Details of the PCB assembly our described below with reference to FIGS. 2 through 6.

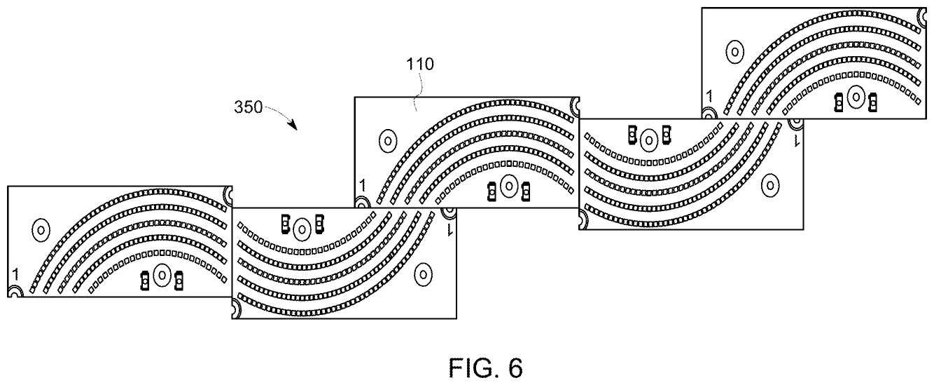

FIG. 2 provides an illustration of an exemplary PCB assembly 100. The PCB assembly 100 includes a plurality of PCBs (110) including a first PCB 110a, a second PCB 110b, a PCB 110c and a PCB 110d. The present invention is not limited to a particular number of PCBs 110 being implemented within the assembly 100 and can vary based on the desired lighting design, for example as depicted in FIGS. 5 and 6. The PCBs 110a through 110d are all formed of the same shape. For example, according to one embodiment, the PCBs 110a-110d are each formed of a rectangular shape. However, the present invention is not limited thereto and the PCBs 110a-110d can be formed of different shapes. According to one embodiment, the PCBs 110a-110d are manufactured by using a scoring machine capable of cutting a series of parallel lines to the edge of a larger PCB sheet, and rotating by approximately 90° to create orthogonal lines thereby creating the rectangular shape of the PCBs 110a-110d. However, the present invention is not limited thereto and the PCBs 110a-110d can be formed of different shapes, for example, the shape of a triangle, hexagon, trapezoid and parallelogram.

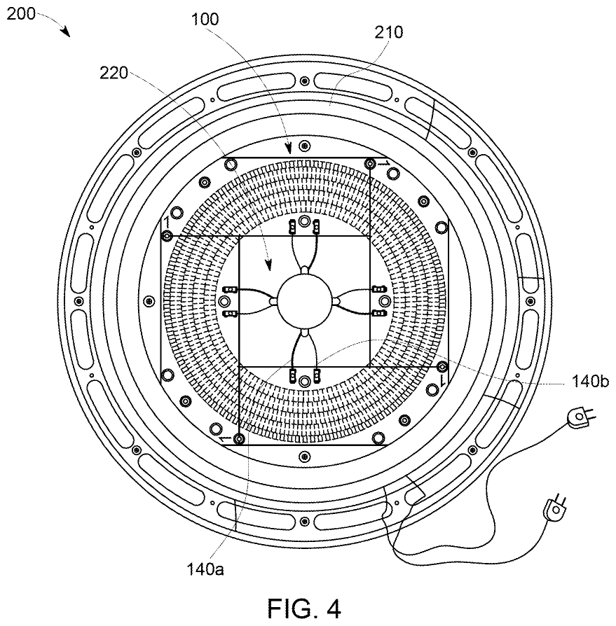

As shown in FIGS. 2 and 3, each PCB 110a-110d includes a plurality of lighting elements 120 disposed thereon to form a desired lighting pattern 125. According to an embodiment, the lighting elements 120 are LEDs. The lighting elements 120 are disposed in a side-by-side configuration in rows. The rows are spaced apart and in parallel, forming a desired lighting pattern 125 (as depicted in FIG. 2) when the PCBs 110a-110d are electrically connected together. According to an embodiment, the lighting elements 120 can be arranged to form either a full circle, half-circle, or ¼ circle arcs.

According to one embodiment, the lighting pattern 125 has a circular form factor, but does not require circular PCB routing to facilitate an electrical connection. The present invention is not limited to the lighting pattern 125 being formed of a circular shape and can therefore vary in shape and size as desired, for example, as shown in FIGS. 5 and 6 discussed below.

In the embodiments, each PCB 110a-110d is formed of a first shape and comprising the lighting elements 120 arranged thereon to form a second shape. A lighting pattern of a desired shape is created with the lighting elements 120 when the PCBs are electrically connected together when the first shape is different from the second shape. As shown in FIGS. 2, 3, and 4, for example, the PCBs 110a-110d are of a rectangular shape while the configuration of the lighting elements 120 thereon form an arc (or a half-moon) shape to create the circular shape lighting pattern 125.

The lighting elements 120 can be semiconductor, organic or polymeric LEDs or similar devices. The lighting elements 120 are configured to receive output power from a lighting driver (not shown) and to emit light as controlled.

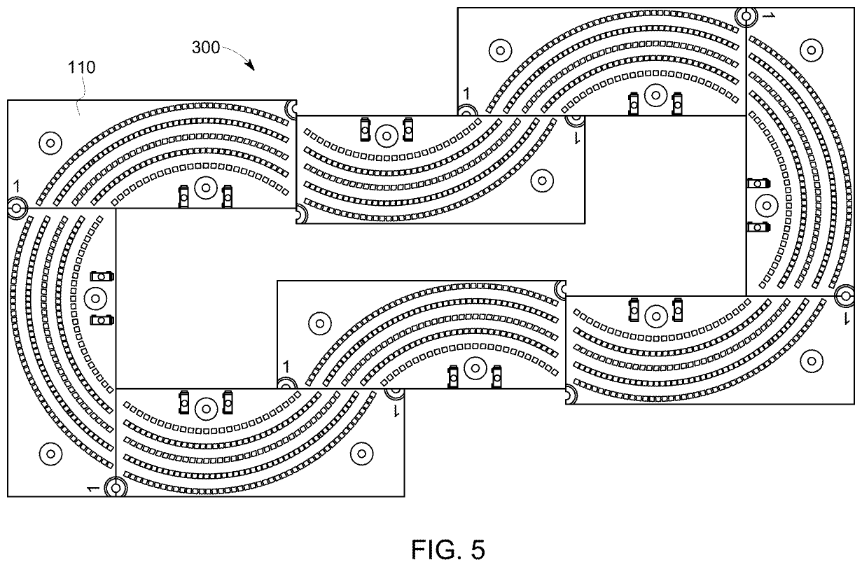

The PCBs 110a-110d are arranged and physically connected to a lighting assembly housing 210 (depicted in FIG. 4), by attachment means 50 at a respective corner of each PCB 110a-110d. In one embodiment, in which the desired lighting pattern is circular, the arrangement of the PCBs 110a-110d is such that fasteners connecting the PCBs 110a-110d to the lighting assembly housing 210 via the attachment means 50 also physically connects PCBs 110a-110d together. In another embodiment, such as those lighting patterns shown in FIGS. 5 and 6 discussed below, the attachment means 50 would affix the PCBs 110 to a lighting assembly housing but not to one another.

Further, as shown in FIGS. 2 and 3, each PCB 110a-110d includes connectors 130a and 130b. The connectors 130a and 130b are for positive and negative electrical terminals to facilitate electrical connection of each PCB 110a-110d. These connectors 130a and 130b are formed at a center area of each PCB 110a-110d and adjacent to an inner row of the lighting elements 120 nearest the center of the PCB assembly 100 when assembled.

In the exemplary embodiments, the connectors 130a and 130b are vertical through board connectors, which extend through a heatsink 220 as depicted in FIG. 4 (e.g., a LED heatsink) situated on a back surface thereof opposite the side having the lighting elements 120 thereon, where the electrical connections occur. The electrical connection to the PCBs 110a-110d can be made with other types of connectors such as push-in, solder pads, or any other suitable connectors.

As further shown in FIG. 4, a lighting assembly 200 is provided and includes a housing 210 for housing the PCB assembly 100 therein. As shown at the heat sink 220, the lighting assembly 200 further includes wiring 140a and 140b arranged thereon for respectively connecting to the positive and negative terminals 130a and 130b of each PCB 110a-110d to provide the electrical connection for supplying power thereto.

FIGS. 5 and 6 depict PCB assemblies according to alternative embodiments of the present invention, with use of the same PCBs shown in FIGS. 2-4 to be connected to form different lighting patterns. For example, as shown in FIG. 5, the PCB assembly 300 includes PCBs 110 arranged to form a complex closed loop shape. In FIG. 6, in the PCB assembly 350 the PCBs 110 may be arranged to form a lighting pattern of serpentine shape.

One of the advantages of the embodiments of the present invention, includes that PCBs of a PCB assembly can be arranged to form a desired lighting pattern thereon, when connected together, without the need for special PCB routing based on the shape of the lighting pattern and the PCB.

This written description uses examples to disclose the invention, including the best mode, and also to enable any person skilled in the art to practice the invention, including making and using any devices or systems and performing any incorporated methods.

The patentable scope of the invention is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal languages of the claims.

What is claimed is:

1. A printed circuit board (PCB) assembly comprising:
a plurality of printed circuit boards to be electrically connected together, and each being formed of a first shape and comprising a plurality of lighting elements arranged thereon to form of a second shape creating a lighting pattern of a desired shape with the plurality of lighting elements, when electrically connected together, wherein the first shape is different from the second shape.

2. The PCB assembly of claim 1, wherein the first shape comprises a rectangle.

3. The PCB assembly of claim 1, wherein the second shape comprises at least one of a full circle, a half-circle, or one-quarter circle arcs.

4. The PCB assembly of claim 1, wherein the shape of the lighting pattern is of at least one of a circle, a serpentine, or complex closed loop shape.

5. The PCB assembly of claim 1, wherein the plurality of lighting elements are arranged in a side-by-side configuration in at least one row along a center region of each printed circuit board.

6. The PCB assembly of claim 1, wherein the plurality of lighting elements are arranged in a side-by-side configuration in a plurality of rows spaced apart in parallel with each other.

7. The PCB assembly of claim 1, wherein the printed circuit boards are arranged and physically connected together and to a housing of a lighting assembly, by attachment means at a respective corner of each printed circuit board, to form the lighting pattern of the plurality of lighting elements thereon.

8. The PCB assembly of claim 1, wherein each printed circuit board further comprises a pair of connectors formed at a center area thereof, to facilitate electrical connection of each printed circuit board.

9. The PCB assembly of claim 7, wherein the pair of connectors extend through a heat sink at a back surface of each printed circuit board opposite a side having the plurality of lighting elements thereon, where the electrical connection occurs.

10. A lighting assembly comprising:
a housing; and
a printed circuit board (PCB) assembly to be housed in the housing and comprising:
a plurality of printed circuit boards to be electrically connected together, and each being formed of a first shape and comprising a plurality of lighting elements arranged thereon to form of a second shape creating a lighting pattern of a desired shape with the plurality of lighting elements, when electrically connected together, wherein the first shape is different from the second shape.

11. The lighting assembly of claim 9, wherein the first shape comprises a rectangle shape.

12. The lighting assembly of claim 9, wherein the second shape comprises at least one of a full circle, a half-circle, or one-quarter circle arcs.

13. The lighting assembly of claim 9, wherein the shape of the lighting pattern is of at least one of a circle, a serpentine, or complex closed loop shape.

14. The lighting assembly of claim 9, wherein the plurality of lighting elements are arranged in a side-by-side configuration in at least one row along a center region of each printed circuit board.

15. The lighting assembly of claim 9, wherein the plurality of lighting elements are arranged in a side-by-side configuration in a plurality of rows spaced apart in parallel with each other.

16. The lighting assembly of claim 9, wherein the printed circuit boards are arranged and physically connected together and to a housing of a lighting assembly, by attachment means at a respective corner of each printed circuit board, to form the lighting pattern of the plurality of lighting elements thereon.

17. The lighting assembly of claim 9, wherein each printed circuit board further comprises a pair of connectors formed at a center area thereof, to facilitate electrical connection of each printed circuit board.

18. The lighting assembly of claim 17, wherein the pair of connectors extend through a heat sink at a back surface of each printed circuit board opposite a side having the plurality of lighting elements thereon, where the electrical connection occurs.

19. The lighting assembly of claim 18, further comprising a pair of wires for respectively connecting to the pair of connectors to facilitate the electrical connection for supplying power thereto.
